(19) United States
(12) Patent Application Publication
(10) Pub. No.: US 2013/0202132 A1
(43) Pub. Date: Aug. 8, 2013

(54) Motion Based Compensation of Downlinked Audio

(71) Applicants: Robert A. Zurek, Antioch, IL (US); Rachid M. Alameh, Crystal Lake, IL (US); William P. Alberth, Prairie Grove, IL (US); Timothy Dickinson, Crystal Lake, IL (US); Thomas Y. Merrell, Beach Park, IL (US); Murthy Pullela, Bangalore (IN)

(72) Inventors: Robert A. Zurek, Antioch, IL (US); Rachid M. Alameh, Crystal Lake, IL (US); William P. Alberth, Prairie Grove, IL (US); Timothy Dickinson, Crystal Lake, IL (US); Thomas Y. Merrell, Beach Park, IL (US); Murthy Pullela, Bangalore (IN)

(73) Assignee: Motorola Mobilitity, Inc., Libertyville, IL (US)

(21) Appl. No.: 13/365,387

(22) Filed: Feb. 3, 2012

(51) Int. Cl. H03G 3/00

(52) U.S. Cl. 381/107

(57) ABSTRACT

Embodiments relate to systems for, and methods of, compensating for movement of a loudspeaker relative to a user's head, where the loudspeaker is present in a mobile device. Example systems and methods produce (300) an electrical signal representative of audio, determine (302) a distance between the device and the user's head and automatically set (304) a gain of the electrical signal in accordance with the distance. Example systems and methods also output (306) audio corresponding to the electrical signal with the gain.

### CROSS-REFERENCE TO RELATED APPLICATION

The present application is related to co-pending U.S. utility patent application entitled “MOTION BASED COMPENSATION OF UPLINKED AUDIO,” bearing Ser. No. ______ by Robert A. Zurek et al., filed concurrently herewith, and the contents thereof are hereby incorporated by reference herein in its entirety.

### FIELD

The present teachings relate to systems for, and methods of, compensating for a varying distance between an electronic loudspeaker in a mobile electronic device and a user's ear(s).

### DESCRIPTION OF DRAWINGS

The accompanying drawings, which are incorporated in and constitute a part of this specification, illustrate embodiments of the present teachings and together with the description, serve to explain the principles of the present teachings. In the figures:

FIG. 1 is a schematic diagram of a mobile device according to various embodiments;

FIG. 2 is a schematic diagram of user interacting with a mobile device according to various embodiments;

FIG. 3 is a flow chart depicting a method of motion based compensation of downlinked audio according to various embodiments;

FIG. 4 is a flow chart depicting a method of intuitive motion based volume adjustment according to various embodiments;

FIG. 5 is a flow chart depicting a method of motion based compensation of uplinked audio according to various embodiments;

FIG. 6 is a flowchart depicting a method of noise abatement in uplinked audio according to various embodiments; and

FIG. 7 is a flowchart depicting a method of compensating for a Doppler effect in uplinked audio according to various embodiments.

### DESCRIPTION OF EMBODIMENTS

Techniques compensate for the effect of a varied distance, and relative movement, between an electronic loudspeaker in a device and a user's ear. In general, as a distance between a loudspeaker and a user's ear increases, the sound pressure of detected audio decreases (correspondingly, as distance decreases, detected sound pressure increases). Certain embodiments compensate for this effect by adjusting a gain of a loudspeaker amplifier in proportion to the distance. Certain embodiments also allow a user to intuitively and efficiently adjust a gain of the loudspeaker in the mobile device by activating a volume set mode. When in the volume set mode, the user may move the mobile device toward or away from his or her head and the gain level will be adjusted in inverse proportion to the distance. The device may be a mobile device or a cellular telephone according to certain embodiments. In some embodiments, the device may be a speakerphone.

According to various embodiments, a method compensates for movement of a loudspeaker relative to a user's head, where the loudspeaker is present in a mobile device. The method includes producing, by the device, an electrical signal representative of audio and determining, by the device, a distance between the device and the user's head. The method also includes automatically setting, by the device, a gain of the electrical signal in accordance with the distance. The method further includes outputting, via the loudspeaker of the device, the electrical signal with the gain.

Reference will now be made in detail to exemplary embodiments of the present teachings, which are illustrated in the accompanying drawings. Where possible the same reference numbers will be used throughout the drawings to refer to the same or like parts.

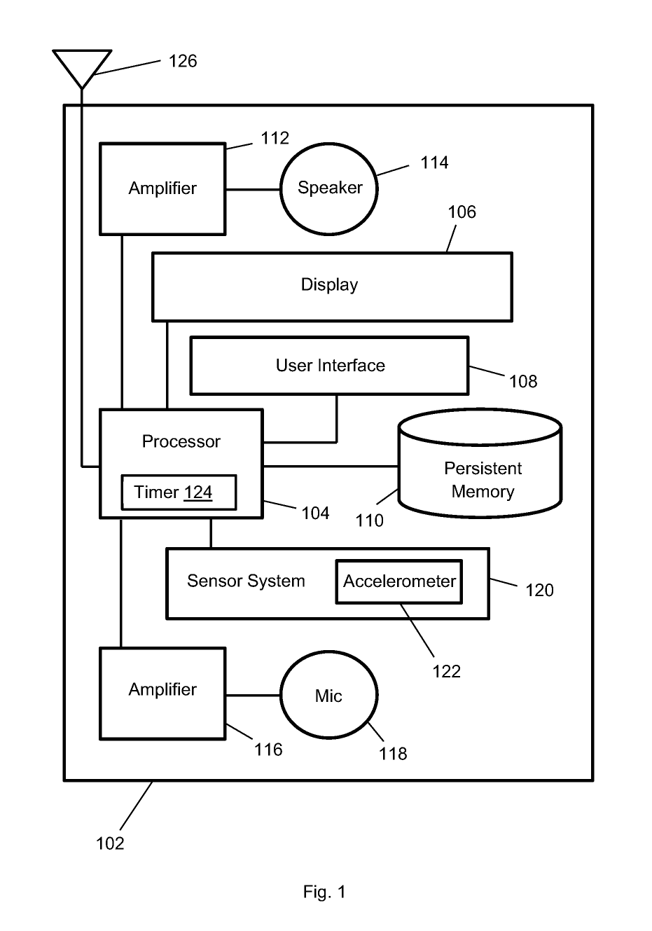

FIG. 1 is a schematic diagram of a device according to various embodiments. Lines between blocks in FIG. 1 indicate communicative coupling and do not necessarily represent direct continuous electrical connection. The device 102 may be, by way of non-limiting example, a mobile device, a cellular telephone, a recorded audio player (e.g., a MP3 player), a personal digital assistant, a tablet computer, or other type of hand-held or wearable computer, telephone, or device containing a loudspeaker or microphone. Mobile device 102 includes processor 104. Processor 104 may be, by way of non-limiting example, a microprocessor or a microcontroller. Processor 104 may be capable of carrying out electronically stored program instructions. Processor 104 may contain or be coupled to timer 124. Processor 104 may be coupled to antenna 126. Processor 104 may be communicatively coupled to persistent memory 110. Persistent memory 110 may include, by way of non-limiting example, one or both of a hard drive and a flash memory device. Persistent memory 110 may store instructions which, when executed by processor 104 in conjunction with other disclosed elements, constitute systems and perform methods disclosed herein.

Processor 104 may be further coupled to display 106 and other user interface 108 elements. Display 106 may be, by way of non-limiting example, a liquid crystal display, which may include a touchscreen. Other user interface 108 elements may be, by way of non-limiting example, a full or partial physical keyboard or keypad. In embodiments where display 106 is a touchscreen, display 106 may be combined with user interface 108 so as to display an active full or partial keyboard or keypad. That is, user interface 108 may include a full or partial virtual keyboard or keypad.

Processor 104 may be further coupled to loudspeaker 114 by way of amplifier 112. Loudspeaker 114 may be, by way of non-limiting example, a loudspeaker of a cellular telephone or audio system. Loudspeaker 114 may be capable of producing sound suitable for a speakerphone mode or a private telephone mode. Amplifier 112 may include a preamplification stage and a power amplification stage. In some embodiments, amplifier 112 may include one or both of a digital-to-analog converter and decoding (e.g., compression, decompression, and/or error correction decoding) circuitry.

Processor 104 may be further coupled to microphone 118 by way of amplifier 116. Microphone 118 may be, by way of non-limiting example, a microphone of a cellular telephone. Microphone 118 may be capable of receiving and converting to electricity sound captured by the cellular telephone. Amplifier 116 may include a preamplification stage. In some embodiments, amplifier 116 may include one or both of an analog-to-digital converter and encoding (e.g., error correction and/or compression encoding) circuitry.

Processor 104 may be further coupled to sensor system 120. Sensor system 120 may be any of several various types. By way of non-limiting example, sensor system 120 may be infrared, acoustic, or photographic. If infrared, sensor system 120 may include an infrared emitter (e.g., a high-power light emitting diode) and an infrared receiver (e.g., an infrared sensitive diode). If acoustic, sensor system 120 may include an ultrasonic transducer or separate ultrasonic emitters and receivers. In some embodiments, microphone 118 may perform ultrasonic reception. If photographic, sensor system 120 may include a camera utilizing, e.g., optics and a charge coupled device. In some embodiments in which sensor system 120 is photographic, one or both of sensor system 120 and processor 104 may employ facial recognition, known to those of skill in the art, capable of determining when a human face is within a depth of field of sensor system 120. Regardless as to the particular technology used by sensor system 120, sensor system 120 may include interpretive circuitry that is capable of converting raw empirical measurements into electrical signals interpretable by processor 104.

Sensor system 120 may further include accelerometer 122, which detects applied linear force (e.g., in one, two or three linearly orthogonal directions). Accelerometer 122 may be, by way of non-limiting example, a micro-electromechanical system (MEMS), capable of determining the magnitude and direction of any acceleration. Sensor system 120 may also include a gyroscope (possibly as, or as part of, accelerometer 122) that detects applied rotational force (e.g., in one, two or three rotationally orthogonal directions). Sensor system 120 may further include a velocity sensor, which detects the velocity of objects relative to a face of the mobile device 102. The velocity sensor may be, by way of non-limiting example, an optical interferometer capable of determining the magnitude and direction of any velocity of the device relative to an object in front of the sensor. The velocity sensor may detect velocity only in a direction normal (i.e., perpendicular) to the face (e.g., display) of the mobile device, or in three orthogonal directions.

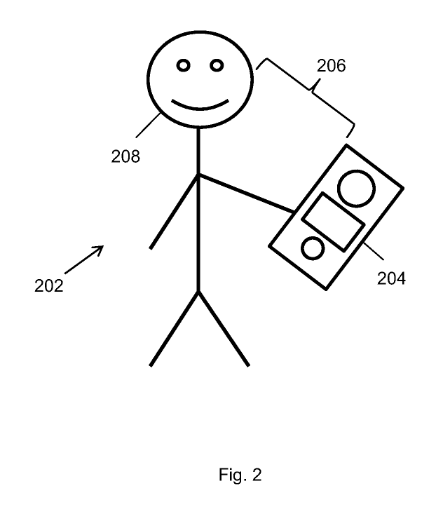

FIG. 2 is a schematic diagram of a user interacting with a mobile device according to various embodiments. In particular, user 202 is depicted as holding mobile device 204, which may be, by way of non-limiting example, mobile device 102 of FIG. 1. User 202 may interact with mobile device by one or both of providing audio input (e.g., voice) and receiving audio output (e.g., audio provided by the device 102). Note that there may not be a consistent distance 206 between the mobile device 204 and the user 202. For a handheld mobile device 204 as depicted, the distance may vary from moment to moment depending on the angle of the hand, wrist, elbow, shoulder, neck, and head of the user. Also, the user may shift the mobile device 204 from one hand to another, put the mobile device 204 down on a table and pace while talking and listening, and many other physical interactions that affect the distance between the mobile device 204 and the user 202 which in turn affect the sound pressure from the loudspeaker of the device as detected by the user's ear(s).

Mobile device 204 is capable of detecting a distance 206 between itself and user's head 208. To that end, mobile device 204 includes a sensor system (e.g., sensor system 120 of FIG. 1). The detected distance may be between the sensor system and a closest point on a user's head, a distance that is an average of distances to a portion of the user's head, or another distance. The sensor system, whether infrared, ultrasonic, or photographic, is capable of determining distance 206 and providing a corresponding representative electrical signal.

For example, if the sensor system is infrared, it may detect an infrared signal sent from mobile device 204 and reflected off of user's head 208. Using techniques known to those of skill in the art, such a reflected signal may be used to determine distance 206. Analogously, if ultrasonic, the sensor system may detect an ultrasonic signal transmitted from mobile device 204 and reflected off of user's head 208. Using techniques known to those of skill in the art, such a reflected signal may be used to determine distance 206. If photographic, the sensor system may use facial recognition logic to determine that user's head 208 is within a depth of field and, using techniques known to those of skill in the art, determine distance 206. Additionally if photographic information is acquired by an autofocus camera, distance 206 can be determined to be the focal distance of the camera's optical system. The autofocus system in this example can focus on the closest object, or on the specific region of the user's head, depending on the autofocus algorithm employed.

Any of the aforementioned techniques (infrared, ultrasonic, photographic) may be used in combination with acceleration data (e.g., detected by accelerometer 122) to calculate additional distances using, by way of non-limiting example, dead reckoning, known to those of skill in the art. For example, if an infrared, ultrasonic, or photographic technique is used to determine an absolute distance at a given time, and a subsequent acceleration in a direction away from the user's head is detected over a particular time interval, then, as known to those of skill in the art, these parameters are sufficient to derive an estimate of the absolute distance at the end (or during) the time interval. Regardless of the specific technology used to determine distance 206, mobile device 204 is capable of such determination.

Sensor systems (e.g., a photographic sensor) can also be used to determine a proportional change in distance by comparing the relative size of features on a user's head (e.g., an eye, an ear, a nose, or a mouth) and determining the proportional change in distance accordingly based on a reference size of the feature. In this way, the proportional change in distance can be used to perform the gain adjustments described herein without having to determine an absolute distance between the mobile device and the user.

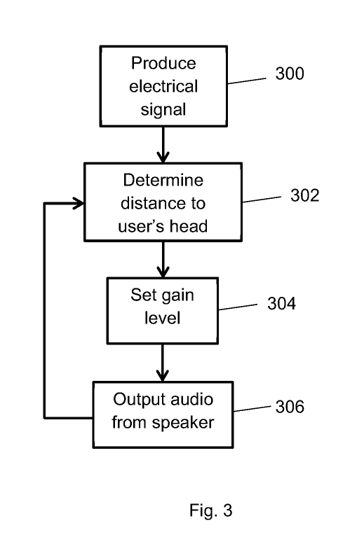

FIG. 3 is a flow chart depicting a method of motion based compensation of downlinked audio according to various embodiments. In general, the perceived volume of audio emitted from a loudspeaker in a mobile device is a function of the distance between the mobile device loudspeaker and the listening user's ear(s). As the device gets further from the user's head, the perceived volume generally decreases. In general, doubling a distance from a sound source results in a decrease in perceived sound pressure of 6.02 dB. The method depicted in FIG. 3 may be used to compensate for perceived volume changes due to varying distance between a user's ear(s) and the loudspeaker emitting audio.

Thus, at block 300, a mobile device (e.g., mobile device 102 of FIG. 1 or 204 of FIG. 2) produces an electrical signal representing downlink audio. The electrical signal may be, by way of non-limiting example, an analog or digital signal representing the voice of a person with whom the user of the mobile device is communicating. Thus, the electrical signal may reflect information received from outside the device. In some embodiments, e.g., mobile devices that play pre-recorded music, the electrical signal may originate internal to the device.

At block 302, the distance between the device and the user's head is determined. As discussed above in reference to FIGS. 1 and 2, there are several techniques that may be employed to that end. For example, infrared distance detection or ultrasonic distance detection may be used. In general, mobile devices such as cellular telephones have a front face, which is generally pointed toward the user's head during operation. Accordingly, employing infrared or ultrasonic techniques to detect the distance to the nearest object before the front face of the mobile device may be implemented to achieve block 302. Alternately, or in addition, photographic facial recognition may be utilized. For such embodiments, the facial recognition techniques may detect the front of a person's face, or a person's face in profile, and thereby determine the distance at issue. The aforementioned techniques may be used alone, in conjunction with one another, or in conjunction with a dead reckoning technique as informed by acceleration (e.g., using accelerometer 122 of FIG. 1) and timing information. Regardless as to the specific technique employed, block 302 results in the mobile device possessing data reflecting a distance from the device to the user's head.

At block 304, the gain level is set in accordance to the distance determined at block 302. In some embodiments, the gain level (e.g., gain of amplifier 112 of FIG. 1) is set in direct proportion to the distance measured. The table below reflects exemplary gain and sound pressure levels in relation to distance, where it is assumed by way of non-limiting example that, prior to any automatic adjustment according to the present embodiment, sound pressure at an initial distance of 1 cm from the source is 90 dB. Other proportionalities are also contemplated.

Output Gain Table

| | Uncompensated | |
|---|---|---|
| | Sound Pressure | |
| Distance | Level | Gain |
| 1 cm | 90.00 dB | 0.00 dB |
| 2 cm | 83.98 dB | 6.02 dB |
| 4 cm | 77.96 dB | 12.04 dB |
| 8 cm | 71.94 dB | 18.06 dB |
| 16 cm | 65.92 dB | 24.08 dB |

In the above table, note that with each doubling of distance comes an additional 6.02 dB of gain used to compensate for the perceived decrease in volume.

At block 306, the audio is output from the loudspeaker. This may be achieved by feeding the output of a power amplifier directly to the loudspeaker (e.g., loudspeaker 114 of FIG. 1).

Flow from block 306 may return back to block 302 so that the gain is repeatedly adjusted. The repetitive adjustment may occur at periodic intervals (e.g., every 0.1 second, 0.5 second, or 1.0 second) as determined using a timer such as timer 124 of FIG. 1. Alternately, or in addition, the repetitive adjustment may be triggered by an event such as a detected acceleration of the device above a certain threshold.

Although an initial setting of 0 dB of gain for a distance of 1 cm is shown in the table above, the user may be more comfortable with another gain setting. Alternatively instead of an increase in gain as the distance is increased, the gain can be implemented as an increase in attenuation as distance is decreased. For example, in the case above, if the gain at 16 cm were to be 0 dB, the gain at 1 cm would then be −24.08 dB, or 24.08 dB of attenuation.

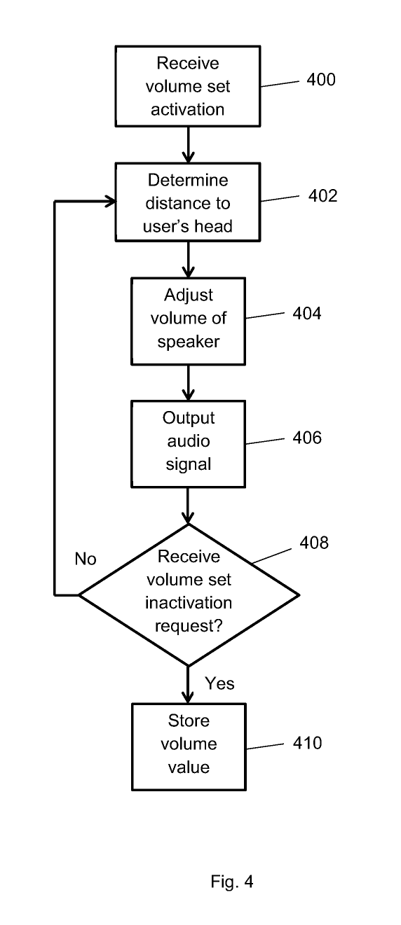

FIG. 4 is a flow chart depicting a method of intuitive motion based volume adjustment according to various embodiments. In general, the technique illustrated by FIG. 4 allows a user to adjust a gain of a mobile device (e.g., mobile device 102 of FIG. 1) loudspeaker using an intuitive, efficient, gesture-based procedure. The technique of FIG. 4 thus allows a user to set a gain for a loudspeaker according to the user's preference. The gain adjusted may be that of a loudspeaker on a cellular phone or other electronic device.

At block 400, the user provides a volume set activation request to a mobile device. The volume set activation request may be the user activating a physical or virtual (e.g., touchscreen) button on the mobile device. Alternately, or in addition, the volume set activation request may be a voice command recognized by the device. The mobile device receives the request and enters a volume adjustment mode, which the user controls as discussed presently. At block 402, the mobile device determines a distance to the user's head using any of the techniques disclosed herein (e.g., infrared, ultrasonic, and/or photographic; with or without dead reckoning).

At block 404, the mobile device adjusts an output gain for the loudspeaker in inverse proportion to the distance. Thus, the farther the mobile device from the user's head, the more the gain level is lowered. Note that the volume adjustment is made relative to the current gain set for the mobile device's loudspeaker. Thus, for example, a user may hold the mobile device 10 cm from the user's head and request activation of the volume set mode according to block 400. If the user brings the mobile device toward the user's head, the mobile device will increase the gain; if the user brings the mobile device away from the user's head, the mobile device will decrease the gain.

The proportionality of change in gain may be linear, quadratic, or another type of proportionality. For example, in some embodiments, each unit distance movement toward or away from the user's head (e.g., 1 cm) may result in an increase or decrease of gain by a fixed amount (e.g., 1 dB). As another example, in some embodiments, each unit distance movement toward or away from the user's head (e.g., 2 cm) may result in an increase or decrease of gain by an amount that is a function (e.g., a quadratic function) of the distance (e.g., 2²=4 dB). Exponential proportionalities are also contemplated. For example, each unit distance movement (e.g., ×cm) may result in an increase or decrease of gain as an exponential function of the distance (e.g., 2^{x} dB).

Other embodiments may adjust loudspeaker gain based on a change in relative distance. Thus, for example, some embodiments may use an initial distance from the user's head as a starting point. Each subsequent halving of the distance between the mobile device and the user's head may result in an increase of gain by a fixed amount (e.g., 6.02 dB), and each doubling of distance from the user's head may result in a decrease in gain by a fixed amount (e.g., 6.02 dB).

At block 406, the device outputs audio (e.g., by way of loudspeaker 114). The audio may be the typical audio output of a cellular telephone (e.g., a remote speaker's voice). Alternately, or in addition, internally-generated audio may be output at block 406 during the gain adjustment process. Such internally-generated audio may be a tone, a plurality of tones, a musical chord, or intermittent outputs of any of the preceding (e.g., 0.1 second tones at 0.5 second intervals). A user may utilize the output audio of block 406 to determine a desired level of output, which corresponds to an internal gain setting of the device. That is, the audio may serve as a feedback mechanism such that the user may accurately adjust the output volume.

At block 408, the device checks if it has received a volume set inactivation request from the user. Reception of such a request causes the device to store 410 its gain level at its current state set during the operations of block 404. This stored value becomes the updated “anchor” for an updated output gain table. In some embodiments, the volume set inactivation request may be the user activating a physical or virtual (e.g., touchscreen) button on the mobile device. In some embodiments, this may be the same button activated at block 400. The volume set inactivation request may also be a voice command recognized by the device. If no activation request has been received, the flow returns to step 402 so that the gain can repeatedly be adjusted.

In other embodiments, when the volume adjustment mode is activated, the adaptive gain control discussed in reference to FIG. 3 is disabled. In this case, as the distance between the device and the user's head decreases, the perceived sound pressure level of the device naturally increases, and as the distance between the device and the user's head increases, the perceived sound pressure level naturally decreases. Thus, step 404 does not change the volume electronically. When the perceived sound pressure level from step 406 is acceptable to the user, the user initiates the volume set inactivation request. The distance adaptive method of FIG. 3 is then reactivated using the current position as the reference gain level. The gain level will then be increased from this reference gain level as the device is moved further from the user's head, or decreased from this reference gain level as the device is moved closer to the user's head as shown in FIG. 3.

In some embodiments, the volume set activation request of block 400 is made by activating and holding down a button (whether physical or virtual). In such embodiments, the volume set inactivation request of block 408 may be made by releasing the same button. Thus, in such embodiments, the user employs the technique of FIG. 4 by initially holding the mobile device at a distance from the user's head, holding down an activation/deactivation button while adjusting the mobile device output gain by moving the mobile device toward or away from the user's head, and finally releasing the button after the user is satisfied with the resulting perceived volume.

In addition, or in the alternative to the manual and/or automatic adjustment of audio output gain, the audio input gain can also be adjusted as discussed below.

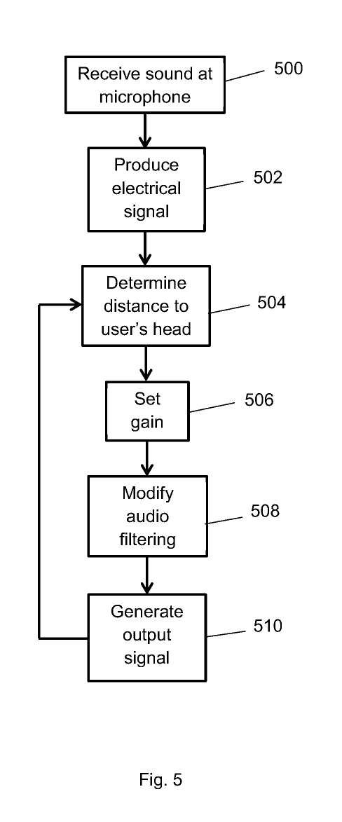

FIG. 5 is a flow chart depicting a method of motion based compensation of uplinked audio according to various embodiments. In general, the volume of audio picked up by a microphone varies with the distance between the microphone and the audio source. As the microphone gets farther away from the audio source, the amplitude of the detected sound decreases; as the microphone gets closer to the source, the amplitude of the detected sound increases. In general, doubling a distance between a sound source and microphone results in a decrease in sound pressure at the microphone of 6.02 dB. The method depicted in FIG. 5 may be used to compensate for sound pressure amplitude changes picked up by a microphone due to a varying distance between a user's mouth and a microphone of a mobile device.

Thus, at block 500, a mobile device (e.g., mobile device 102 of FIG. 1 or 204 of FIG. 2) receives sound at a microphone (e.g., microphone 118 of FIG. 1). At block 502, the sound is converted to an electrical signal. The electrical signal may be, by way of non-limiting example, an analog or digital signal representing the voice of user of the mobile device (including ambient noise).

At block 504, the distance between the device and the user's head is determined. As discussed above in reference to FIGS. 1 and 2, there are several techniques that may be employed to that end. For example, infrared distance detection or ultrasonic distance detection may be used. In general, mobile devices such as cellular telephones have a front face, which is generally pointed toward the user's head during operation. Accordingly, employing infrared or ultrasonic techniques to detect the distance to the nearest object before the front face of the mobile device may be implemented to achieve block 504. Alternately, or in addition, photographic facial recognition may be utilized. For such embodiments, the facial recognition techniques may detect the front of a person's face, or a person's face in profile and thereby determine the distance. Dead reckoning, as informed by acceleration information (e.g., gathered by accelerometer 122 of FIG. 1) may be performed in addition or in the alternative. Regardless as to the specific technique employed, block 504 results in the mobile device acquiring data reflecting a distance from the device to the user's head.

At block 506, the mobile device sets a gain of an amplifier of the electrical signal. In some embodiments, the gain level (e.g., gain of amplifier 116 of FIG. 1) is set in direct proportion to the distance determined at block 504. The amount of gain may compensate for the physical fact that as a distance between a user's mouth and the microphone increases, the detected sound at the microphone decreases. As discussed above, each doubling of distance results in a reduction of 6.02 dB of detected sound. Accordingly, the gain set at block 506 increases in a similar proportion. The following table illustrates an exemplary gain schedule, assuming a 0 dB gain in the amplifier when the user's mouth is a distance of 1 cm from the microphone.

Input Gain Table

| | Uncompensated | |
|---|---|---|
| | Sound Pressure | |
| Distance | Level | Gain |
| 1 cm | 105.00 dB | 0.00 dB |
| 2 cm | 98.98 dB | 6.02 dB |
| 4 cm | 92.96 dB | 12.04 dB |
| 8 cm | 86.94 dB | 18.06 dB |
| 16 cm | 80.92 dB | 24.08 dB |

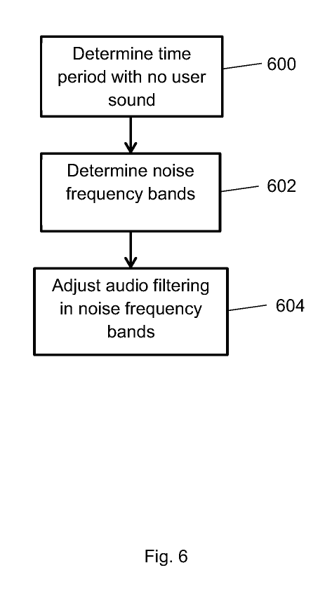

At block 508, audio filtering is modified to compensate for a so-called noise pumping effect. Specifically, if gain increases according to block 506, the noise within the captured audio also increases. Accordingly, if gain is increased by a certain number of decibels, a noise filter may be set to reduce noise by a corresponding or identical amount. The filter may be, by way of non-limiting example, a finite impulse response (FIR) filter set to filter noise at particular frequencies at which it occurs. Further details of a particular technique according to block 508 are discussed below in reference to FIG. 6.

At block 510, an output signal is generated. The output signal may be the result of the gain adjustment of block 506 and the noise reduction of block 508 applied to the electrical signal received at block 502. In some embodiments, the output signal is an analog signal to be stored in the mobile device; in other embodiments, the output signal is transmitted, e.g., to a cellular tower.

Flow from block 510 may return back to block 504 so that the gain may be repeatedly adjusted. The repetitive adjustment may occur at periodic intervals (e.g., every 0.1 second, 0.5 second, or 1.0 second) as determined using a timer such as timer 124 of FIG. 1. Alternately, or in addition, the repetitive adjustment may be triggered by an event such as a detected acceleration of the device above a certain threshold.

FIG. 6 is a flowchart depicting a method of noise abatement in uplinked audio according to various embodiments. The technique discussed with reference to FIG. 6 may be implemented, by way of non-limiting example, as part of block 508 of FIG. 5. In general, the technique discussed in reference to FIG. 6 serves to vary the amplitude in each frequency band of noise dynamically with the change in gain achieved at block 506 of FIG. 5 such that the overall signal-to-noise level is more consistent from time to time (or frame to frame, if frame-based signal processing is implemented). Thus, at block 600, a time period in which the user is not supplying sound to the microphone is identified. This may be performed, e.g., by setting a threshold and detecting when a detected sound level falls below the threshold or by using a voice activity detector (VAD) to detect when voice is not present in the microphone signal. The time period in which the user is not supplying sound is assumed to contain sound consisting mostly of noise.

At block 602, the frequency bands of the sound in association with block 600 are determined. This may be achieved using, for example, a Fourier transform or by dividing the audio spectrum into sub-bands. The frequency bands determined at block 602 represent the primary bands that contain the most noise. At block 604, audio filtering levels, or sub-band spectral suppression levels, are adjusted to reduce noise in the bands identified in block 602. The amount of reduction (or increase) may correspond with the amount of gain added (or reduced) at block 506 of FIG. 5.

Thus, for example, if a particular band identified as containing of mostly noise has a typical suppression value of, for example, 20 dB, and an additional 6 dB of gain is imposed at block 506 of FIG. 5 due to a user moving a mobile device away from the user's mouth, the noise suppression value for the filter at the particular band may be changed by a corresponding 6 dB, for a 26 dB suppression value. Likewise, if gain is reduced by 4 dB at block 506 of FIG. 5 due to a user moving the mobile device closer to the user's head, the suppression of the particular band may be set to 20 dB−4 dB=16 dB. This process may be performed for each noise band identified at block 602. The particular values presented herein are for illustration only and are not limiting.

The technique of FIG. 6 may be performed dynamically, periodically, or whenever a period of time in which no user sound is detected. Thus, the technique of FIG. 6 may be performed at block 508 of FIG. 5, but may also, or in the alternative, be performed at other times (e.g., at or between any of the blocks of FIG. 5).

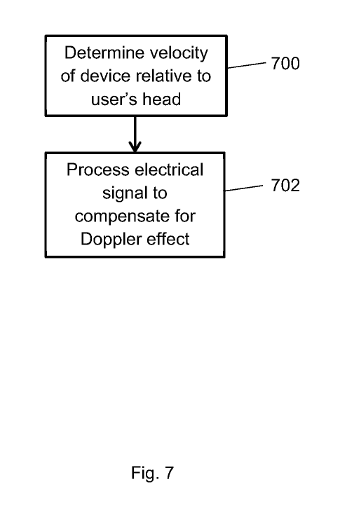

FIG. 7 is a flowchart depicting a method of compensating for a Doppler effect in uplinked audio according to various embodiments. In general, if a user's mouth travels at a non-zero velocity relative to a microphone (e.g., microphone 118 of FIG. 1) while talking, the sound detected by such microphone will be pitch shifted according to the Doppler effect. The technique disclosed in reference to FIG. 7 may be used to compensate for such pitch shifting. In particular, the technique of FIG. 7 may be implemented together with the techniques discussed in any, or a combination, of FIGS. 3-6.

Thus, at block 700, a velocity of the mobile device (e.g., mobile device 102 of FIG. 1) relative to a user's head is determined. The techniques disclosed herein for determining a distance between a device and a user's head (infrared, ultrasonic, photographic, integration of acceleration) may be employed to determine velocity. More particularly, the disclosed distance-determining techniques may be repeated at short intervals (e.g., 0.01 seconds, 0.1 seconds) in order to detect changes in distance. Velocity may be calculated according to the changes in distance and corresponding time interval over which the distance changes are determined according to the formula v=Δd/Δt, where v represents velocity, Δd represents change in distance, and Δt represents change in time. Alternately, or in addition, information received from an accelerometer (e.g., accelerometer 122 of FIG. 1) may be used to determine relative velocity. Alternately, or in addition, the velocity can be taken directly from a velocity sensor contained in, e.g., sensor system 120 of FIG. 1.

Alternative techniques for determining device velocity can also be used when either distance or acceleration are sampled at a repetitive rate. For example if the distance or acceleration is sampled many times each second at a constant rate, a distance or acceleration time signal can be created. Because the velocity is the derivative of the distance time signal or the integral of the acceleration time signal, the velocity can be calculated in either the time or frequency domain. Suitable techniques include differentiating the distance signal in the time domain or integrating the acceleration signal in the time domain. An alternative technique is to convert the time signal into the frequency domain and either multiply each fast Fourier transform (FFT) bin value of the distance signal by the frequency of each FFT bin or divide each FFT bin value of the acceleration signal by the frequency of each FFT bin.

At block 702, the sound is adjusted to account for any Doppler shift caused by the velocity detected at block 700. In particular, the mobile device may include a look-up table or formula containing correspondences between velocity and pitch shift. After the velocity is determined at block 700, the corresponding pitch shift may be determined by such table or formula. The pitch shift may be adjusted in real-time using resampling technology to pitch shift or frequency scale, as is known in the art.

If direct velocity sensing, acceleration sensing, or proportional distance measurement are utilized, the Doppler shift compensation can be implemented without knowing the absolute distance between the mobile device and the user, just as the gain compensation can be implemented using only a proportional distance measure. In the cases of direct velocity sensing or acceleration sensing, this would not require any distance information to perform the Doppler shift. Thus the Doppler compensation can operate independent from a distance sensing operation.

In another embodiment, the method of compensating for a Doppler effect in FIG. 7 can be applied to downlink audio. As the loudspeaker in the device moves relative to the user's ears, a Doppler shift is present in the audio reaching the user's ears. The same methods of determining velocity for the uplink case (infrared, ultrasonic, photographic, velocity sensing, integration of acceleration data) can be used to determine velocity in the down link case. After the velocity of the device relative to the user's head is known, the audio being sent to the loudspeaker can be preprocessed using known pitch shifting techniques to adjust the Doppler shift in the audio signal perceived by the user (e.g., after step 304 of FIG. 3).

In some embodiments, both the uplink and down link audio can be modified simultaneously to compensate for amplitude modulation as well as Doppler shift in the uplink and down link audio signals.

The foregoing description is illustrative, and variations in configuration and implementation may occur to persons skilled in the art. Other resources described as singular or integrated can in embodiments be plural or distributed, and resources described as multiple or distributed can in embodiments be combined. The scope of the present teachings is accordingly intended to be limited only by the following claims.

1. A method of compensating for movement of a loudspeaker relative to a user's head, wherein the loudspeaker is present in a device, the method comprising:
producing, by the device, an electrical signal representative of audio;
determining, by the device, a distance between the device and the user's head;
setting, by the device, a gain of the electrical signal in accordance with the distance;
receiving a volume set activation request;
determining, by the device, a change in distance between the device and the user's head relative to the distance determined previously;
adjusting the gain of the electrical signal in inverse proportion to the change in distance between the device and the user's head; and
outputting audio, via the loudspeaker of the device, corresponding to the electrical signal with the gain as adjusted.

2. The method of claim 1 wherein the adjusting comprises:
increasing the gain of the electrical signal when the distance between the device and the user's head decreases; and
decreasing the gain of the electrical signal when the distance between the device and the user's head increases.

3. The method of claim 1, further comprising:
determining, by the device, a velocity of the device relative to the user's head;
processing the electrical signal representative of audio to compensate for a Doppler effect caused by the velocity.

4. The method of claim 1, wherein the device comprises a front of the device, and wherein the determining, by the device, the distance between the device and the user's head comprises:
determining, by the device, a distance between the front of the device and an object situated before the front of the device.

5. The method of claim 4, wherein the determining, by the device, the distance between the front of the device and the object situated before the front of the device comprises:
sending an infrared signal or an ultrasonic signal from a front face of the device to the object.

6. The method of claim 1, wherein the determining, by the device, the distance between the device and the user's head comprises:
automatically detecting a human face.

7. The method of claim 1, further comprising:
periodically repeating the steps of determining and setting.

8. The method of claim 1, further comprising:
in response to detecting an acceleration of the device exceeding a predetermined threshold, repeating the steps of determining and setting.

9. An apparatus for compensating for movement of a loudspeaker relative to a user's head, wherein the loudspeaker is present in a device, the apparatus comprising:
a source of an electrical signal representative of audio;
a sensor system configured to determine a distance between the device and the user's head;
a user interface configured to receive volume set activation request;
logic, coupled to the user interface and the sensor system, configured to set a gain of the electrical signal in accordance with the distance and configured to adjust the gain of the microphone inversely proportional to a change in distance between the device and the user's head when the volume set activation request is received;
an amplifier, coupled to the source and the logic; and
a loudspeaker, operably coupled to the amplifier, to receive the electrical signal representative of the audio with the gain as adjusted by the logic.

10. The apparatus of claim 9 wherein the logic increases the gain of the electrical signal when the distance between the device and the user's head decreases and decreases the gain of the electrical signal when the distance between the device and the user's head increases.

11. The apparatus of claim 9, wherein the device comprises a cellular telephone.

12. The apparatus of claim 9, further comprising:
means for determining, by the device, a velocity of the loudspeaker relative to the user's head;
logic configured to process the electrical signal representative of audio to compensate for a Doppler effect caused by the velocity.

13. The apparatus of claim 9, wherein the sensor system comprises at least one of: an infrared sensor, an ultrasonic sensor, or a camera.

14. The apparatus of claim 9, wherein the sensor system comprises an accelerometer.

15. The apparatus of claim 9, wherein the apparatus is a mobile telephone.

16. The apparatus of claim 9, further comprising:
logic configured to revise a determination of the distance between the device and the user's head whereby a revised distance is determined, and
a timer configured to periodically trigger a redetermination of the gain of the electrical signal in accordance with the revised distance.

17. The apparatus of claim 9, wherein the sensor system comprises an accelerometer, and wherein the amplifier is further configured to automatically redetermine the gain of the electrical signal, in accordance with a revised distance, in response to the accelerometer detecting an acceleration of the apparatus exceeding an predetermined threshold.
